(19) United States
(12) Patent Application Publication
(10) Pub. No.: US 2018/0175297 A1
(43) Pub. Date: Jun. 21, 2018

(54) Screen Printing Systems and Techniques for Creating Thin-Film Transistors Using Separated Carbon Nanotubes

(71) Applicant: University of Southern California, Los Angeles, CA (US)

(72) Inventors: Chongwu Zhou, San Marino, CA (US); Xuan Cao, Monterey Park, CA (US); Haitian Chen, Los Angeles, CA (US); Bilu Liu, Los Angeles, CA (US); Yu Cao, Los Angeles, CA (US); Xiaofei Gu, Los Angeles, CA (US); Wenli Wang, Los Angeles, CA (US); Fanqi Wu, Los Angeles, CA (US)

(21) Appl. No.: 15/534,444

(22) PCT Filed: Dec. 9, 2015
(86) PCT No.: PCT/US15/64830

§ 371 Date: Jun. 8, 2017

Related U.S. Application Data
(60) Provisional application No. 62/089,797, filed on Dec. 9, 2014.

(51) Int. Cl. H01L 51/00; H01L 51/05; H01L 51/10; H01L 27/32

(52) U.S. Cl. CPC H01L 51/0022; H01L 51/0003; H01L 51/0048; H01L 51/0097; H01L 27/3274; H01L 51/0541; H01L 51/0558; H01L 51/105; H01L 51/0525

(57) ABSTRACT

A method of fabricating a thin film transistor, the method includes applying a first ink containing metallic particles to a first screen mask, and using the first screen mask to deposit the first ink to form a source electrode and a drain electrode on a substrate bearing a layer of carbon nanotubes (CNT). The method includes applying a second ink containing a dielectric material to a second screen mask, and using the second screen mask to deposit the second ink to form a layer of the dielectric material on the layer of CNT between the source electrode and the drain electrode. The method includes applying a third ink containing metallic particles to a third screen mask, and using the third screen mask to deposit the first ink to form a metallic gate electrode on the layer of the dielectric material to form the thin film transistor.

### BACKGROUND

There is tremendous interest in printing technology for manufacturing electronics. Compared with traditional fabrication approaches that use multi-staged photolithography and vacuum deposition, printing is a cost-effective and scalable technology with high throughput. Printing is also highly compatible with low-temperature processing, which is useful for mass production of large-area flexible electronics at extremely low cost. Among various kinds of printed electronics, separated single-wall carbon nanotube (SWCNT) thin-film transistors (TFTs) have attracted growing attention due to their high mobility, high on/off ratio, low operation voltage, and potential application in flexible electronics. Low-cost printed SWCNT TFTs and integrated circuits with high performance are thus desired.

Printing techniques can be mainly divided into two groups. Aerosol jet printing and ink-jet printing are examples of high registration accuracy printing. Ink-jet or aerosol jet printing can provide high printing resolution and uniformity by allowing the production of printed devices that have small dimensions. Gravure printing and flexographic printing are examples of high scalability and high throughput printing.

### SUMMARY

This disclosure relates to screen printing methods and systems capable of fabricating fully printed high-performance thin-film transistors (TFT). The methods and systems disclosed herein can increase scalability and throughput for mass production. In addition, printed electronics that do not rely on ink-jet or aerosol-jet printing, can be produced at reduced costs.

The methods and systems disclosed herein improve upon the quality of active channel materials in TFT and the quality of the printed layers compared to gravure-printing-based roll to roll (R2R) processes that have been used for the manufacturing of carbon nanotube (CNT) radio-frequency identifications, full adders and D flip-flops.

Screen printing, in which screen masks are used to deposit materials onto large-area substrates with high throughput, is a scalable printing technique. Large-area substrates are larger than conventional semiconductor wafers, for example, larger than 12 inches wafers, or on the order of several meters. High throughput can mean a processing speed (i.e., printing speed) of, for example, more than 2 m/s, more than 3 m/s, more than 4 m/s, or more than 5 m/s. Benefitting from its simplicity, scalability and environment-friendly process, this technique can be used for mass production of large-area electronics at very low cost. Screen printing has at least two advantages compared to other scalable printing techniques such as gravure or flexographic printing. First of all, the masks for screen printing are usually made of fabric or stainless steel mesh, which can be more cost-effective than engraved metal masks for gravure printing. The second advantage is the ease with which alignment between the screen mask and the substrate can be performed before (e.g., immediately before) printing, as the screen mask is semitransparent, and both the screen mask and the substrate are planar. These advantages enable alignments to be made in a parallel-plate fashion with good accuracy. Compared to gravure printing and flexographic printing, which usually have either the mask or the substrate on a roller, alignment in both X and Y directions can be more easily achieved using screen printing, making the screen printing technique especially amenable to the fabrication of multilayered structures. In contrast to screen-printed organic TFTs, the performances of the systems disclosed herein are not limited by the inherent properties of the organic channel materials.

The fully printed top-gated CNT thin-film transistors on rigid and flexible substrates disclosed herein exhibit good performance, with a mobility up to 7.67 cm²V⁻¹s⁻¹, an on/off ratio of 10⁴-10⁵, minimal hysteresis, and a low operation voltage (<10 V). In addition, flexible printed CNT thin-film transistors (e.g., bent with a radius of curvature of down to 3 mm) also have outstanding mechanical flexibility and are able to drive organic light-emitting diode. The high performance of the fully screen-printed SWCNT thin-film transistors makes screen-printing an outstanding technique for obtaining low-cost, scalable, and reliable high-performance nanotube thin-film transistors for applications in display electronics. Moreover, this technique may be used to fabricate thin-film transistors based on other materials used in large-area flexible macroelectronics and low-cost display electronics.

In one aspect, a method of fabricating a thin film transistor includes applying a first ink containing metallic particles to a first screen mask, using the first screen mask to deposit the first ink to form a source electrode and a drain electrode on a substrate bearing a layer of carbon nanotubes (CNT), applying a second ink containing a dielectric material to a second screen mask, using the second screen mask to deposit the second ink to form a layer of the dielectric material on the layer of CNT between the source electrode and the drain electrode, and applying a third ink containing metallic particles to a third screen mask. The method includes using the third screen mask to deposit the first ink to form a metallic gate electrode on the layer of the dielectric material to form the thin film transistor.

Implementations can include one or more of the following features. The method can include etching away CNT from regions of the substrate not covered by the source electrode, the drain electrode and the dielectric material. The method can include depositing the CNT on the substrate by immersing the substrate in a solution of CNT. The substrate can be functionalized with poly-L-lysine and the carbon nanotubes can include semiconductor-enriched single-wall carbon nanotubes (SWCNT). The dielectric material can include barium titanate. The method can include aligning the second screen mask and the substrate before depositing the dielectric material. Both the second screen mask and the substrate can be planar. The second screen mask can be semi-transparent. The substrate can include a flexible substrate. The flexible substrate can include polyethylene terephthalate (PET) and a mobility of the thin film transistor can be reduced by less than 20% when the thin film transistor is bent to a radius of curvature of less than 3 mm. The method can include controlling a thickness of the source electrode and the drain electrode by selecting a first dilution ratio for the first ink to be deposited as the source electrode and the drain electrode on the substrate. The method can include controlling a thickness of the layer of the dielectric material by selecting a second dilution ratio for the second ink. The second dilution ratio can determine a viscosity of the second ink. The thin film transistor can have an on-current of at least 3 μA and a peak transconductance of at least 0.27 μS/mm. The thin film transistor can have a mobility between 7-7.7 cm²V⁻¹s¹ and an on/off ratio of between 10⁴ and 10⁵. Applying the first ink on the first screen mask can include using a device to spread the first ink across the screen mask at a first pressure, and forming the source electrode and the drain electrode can include squeezing the first ink through a mesh of the screen mask onto the substrate. The device can include a squeegee and an edge of the squeegee contacts the first screen mask, The squeegee can be configured to make an angle of between 50 to 80 degree with the substrate. A printing speed of the deposition of the source electrode and the drain electrode, the dielectric material, and the gate electrode can depend on a rate at which the first ink, the second ink, and the third ink are squeezed through the first, second, and third masks, respectively.

The method can further include providing a clearance of between 1 mm and 1.5 mm between the first screen mask and the substrate prior to depositing the source electrode and drain electrode on the substrate. The method can include providing a clearance of between 1.25 mm and 1.75 mm between the second screen mask and the substrate prior to depositing the layer of the dielectric material between the source electrode and the drain electrode. The method can include providing a clearance of between 1 mm to 1.5 mm between the third screen mask and the substrate prior to depositing the gate electrode on the dielectric material. The method can include heating the source electrode and the drain electrode at a temperature between 120 to 160° C. after they have been deposited. The first screen mask can include a metal mesh, the metal mesh can include a network of wires having a wire diameter of between 28-40 microns and an opening ratio of at least 40%. The thin film transistor can be printed on the substrate with a resolution of 25 μm.

A single-wall carbon nanotubes (SWCNT) thin film transistor can be fabricated using the method. The thin film transistor can be formed on a rigid Si/SiO₂ substrate and can exhibit current on/off ratio of ˜3×10⁴, and a normalized peak transconductance of ˜0.43 μS/mm at V_{DS}=−1 V, where V_{DS} is the voltage between the source electrode and the drain electrode. A channel length of the thin film transistor can be between 90 to 120 μm and a width of the thin film transistor can be between 900 μm and 1100 μm.

An electronic display can include a top-gated thin film transistor having a gate electrode, a source electrode and a drain electrode fabricated using the method. An external organic light emitting diode (OLED) can be connected to the top-gated thin film transistor. A driving current of between 10-25 ρA can flow through the OLED when a gate voltage of 5V is applied to the gate electrode and a drain voltage of 5V is applied to the drain electrode.

The details of one or more embodiments of the subject matter described in this specification are set forth in the accompanying drawings and the description below. Other features, aspects, and advantages of the invention will become apparent from the description, the drawings, and the claims.

### BRIEF DESCRIPTION OF THE DRAWINGS

FIG. 1A is a schematic diagram showing a fabrication process of fully printed top-gated SWCNT TFTs.

FIG. 1B is a schematic diagram showing a configuration of a fully printed TFT on a poly(ethylene terephthalate) (PET) substrate.

FIG. 1C is a schematic diagram of a screen printing system.

FIG. 1D is an optical image of a fully printed TFT array on a 4 inch Si/SiO₂ wafer.

FIG. 1E is an optical image of a 12×12 cm PET sheet containing a fully printed TFT array.

FIG. 1F is a field emission scanning electron microscopy (FE-SEM) image of a deposited SWCNT film.

FIG. 2A shows a top schematic diagram and a bottom SEM image of a dielectric layer between two electrodes.

FIG. 2B shows a top schematic diagram and a bottom SEM image of a dielectric layer between two electrodes.

FIG. 3A shows thicknesses of printed dielectric layer as a function of dilution ratios of an ink containing dielectric material.

FIG. 3B shows thicknesses of printed electrodes as a function of dilution ratios of an ink containing metallic particles.

FIG. 3C shows transfer (I_{D}-V_{G}) characteristics of TFTs printed with inks of different dilution ratios (Vₛₒₗ/Vₘₖ), measured at V_{DS}=−1 V.

FIG. 3D shows transconductance as a function of gate voltage.

FIG. 4A shows a profile of an electrode.

FIG. 4B shows a profile of the dielectric layer.

FIG. 4C shows a profile of the gate electrode.

FIG. 5A shows a double-sweep of transfer characteristics of a representative TFT on Si/SiO₂ substrate measured at V_{DS}=−1 V.

FIG. 5B shows transfer characteristics of the TFT shown in FIG. 5A under different drain voltages (from −1 to −3 V in 0.5 V steps).

FIG. 5C shows output characteristics of the device shown in FIG. 5A in triode regime.

FIG. 5D shows output characteristics of the device shown in FIG. 5A in saturation regime.

FIG. 6 shows gate leakage current of a printed SWCNT TFT as a function of gate voltage (V_{G}) at a drain-source voltage (V_{DS}) of −1 V.

FIG. 7A shows an optical image of electrical measurements on a fully printed flexible SWCNT TFTs on PET while bent.

FIG. 7B shows transfer (I_{D}-V_{G}) characteristics of a fully printed flexible SWCNT TFTs on PET measured at V_{DS}=−1 V when not bent and under different bending conditions at different radii of curvature (R).

FIG. 7C shows the field-effect mobility of the TFT shown in FIG. 7B.

FIG. 7D shows Iₒₙ/I_{off} ratio plotted as a function of bending radius of curvature.

FIG. 8A shows a statistical analysis of the field-effect mobility of 15 fully screen printed SWCNT TFTs.

FIG. 8B shows a statistical analysis of the current on/off ratio of 15 fully screen printed SWCNT TFT.

FIG. 8C shows a statistical analysis of the on-current density of 15 fully screen printed SWCNT TFT.

FIG. 8D shows a statistical analysis of the threshold voltage (Vₜₕ) of 15 fully screen printed SWCNT TFT.

FIG. 9 shows a schematic diagram of the structure of the external OLED.

FIG. 10A shows I_{OLED}-V_{G} family curves of a fully printed SWCNT TFTs for OLED control.

FIG. 10B shows I_{OLED}-V_{SS} family curves of a fully printed SWCNT TFTs for OLED control.

FIG. 10C shows optical images of external OLED intensity change versus V_{G}.

### DETAILED DESCRIPTION

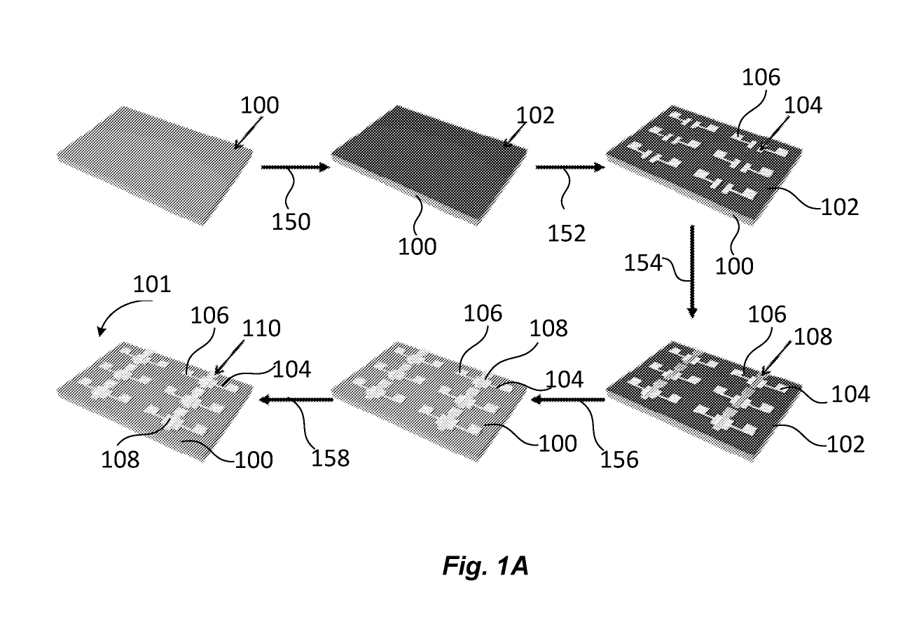

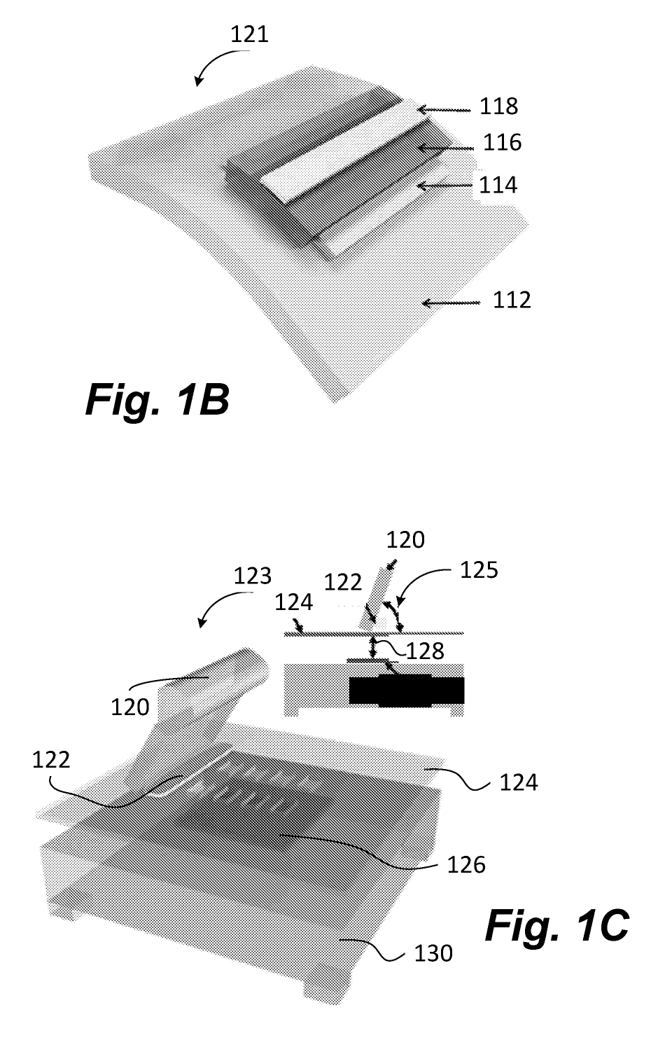

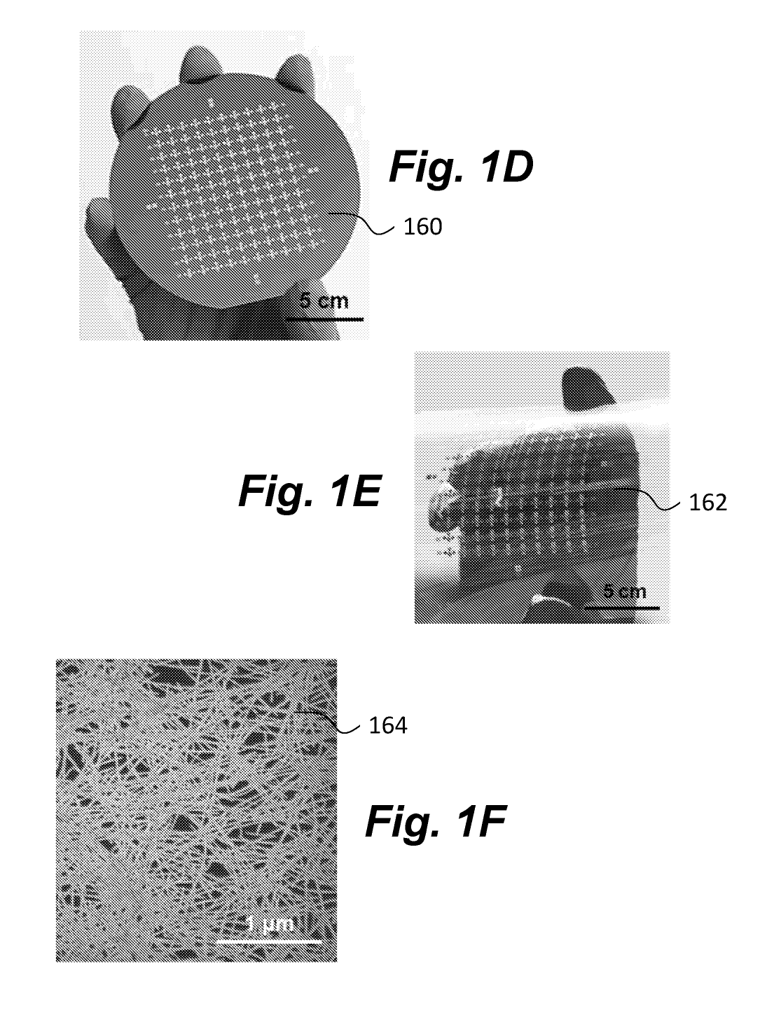

FIG. 1A illustrates a process of fabricating printed TFTs 101 on a substrate 100. The substrate 100 can include a rigid substrate such as a Si/SiO₂ wafer or a flexible substrate, such as a poly(ethylene terephthalate) (PET) substrate. A surface of the substrate 100 is first functionalized with a suitable chemical, such as poly-L-lysine and then a layer, for example, a uniform layer of random SWCNT network 102 is formed by immersing the substrate 100 into a semiconductor-enriched SWCNT solution for, for example, 35 minutes in step 150. Thereafter, in step 152, a metallic source electrode 104, and a metallic drain electrode 106 are patterned on the substrate 100 by screen printing. The source electrode 104 and drain electrode 106 can be formed of silver (Ag). After the source electrode 104 and the drain electrode 106 are printed on the layer of SWCNT, dielectric patterning occurs in step 154. A dielectric layer 108 is deposited, using screen printing, between the source electrode 104 and the drain electrode 106. The dielectric layer 108 can be made of a dielectric material such as barium titanate (BTO). After the dielectric layer 108 is deposited, SWCNT not covered by the electrodes and BTO dielectric are etched away in step 156. In the last step 158, a gate electrode 110 is printed on top of the dielectric layer 108. The gate electrode 110 can also be formed of Ag.

For the deposition of separated nanotubes (i.e., nanotubes that have been separated into either semiconducting nanotubes or conducting nanotubes), the substrates of Si/SiO₂ or PET can be first cleaned with oxygen plasma under 100 watts for 90 seconds. The Si substrate can have an oxide layer of about 300 nm. The PET substrate can have a thickness of 200 μm. The PET substrate can be obtained, for example, from Asada Mesh Co, Ltd. Of Osaka, Japan.

Then the substrates were immersed in poly-L-lysine aqueous solution (0.1% w/v, TED PELLA, Inc., or Redding, Calif.) for 8 minutes to functionalize the surface. This step was followed by rinsing the functionalized substrate using deionized (DI) water. Later, SWCNT network can be deposited by immersing the substrate in purified semiconductor-enriched CNT solution (IsoSol-S100, #23-081, Nanointegris Technologies Inc. of Menlo Park, Calif.) for 35 minutes. After rinsing with DI water and being dried using nitrogen gas flow, the samples were baked on a hotplate at 120° C. for 1 hour. The baking is done after each printing step (i.e., once after the source and drain electrodes are printed, once after the dielectric layer is deposited, and once after the gate electrode is deposited). After printing the source electrode, the drain electrode and the dielectric layer, unwanted SWCNTs not covered by these printed layers can be etched using oxygen plasma (100 W) for 80 s.

Semiconductor-concentrated CNT solution is suitable for use as channel material. High-k barium titanate (BTO)/poly (methyl methacrylate) hybrid ink printed as gate dielectric can improve the mobility (μ) and on/off ratio of the printed SWCNT devices. Moreover, the printed devices can have low operation voltage (<10 V) and outstanding mechanical bendability.

FIG. 1B shows a schematic of a fully printed TFT 121 on a PET substrate 112. Similar to the process outlined for TFT 101, SWCNT are deposited on the PET substrate 112 before source and drain electrodes 114, a dielectric layer 116, and a top gate 118 are screen printed on the PET substrate 112. The dielectric layer 116 can be formed from BTO and the electrodes can be formed from Ag.

FIG. 1C is a schematic diagram exemplifying a screen printer 123 and the screen printing process. Ink 122 is first applied on a patterned area of a screen mask 124, for example, by a stainless steel spatula and then spread by a squeegee 120 over the whole patterned area. A substrate 126 is arranged under the mask screen 124 and separated from it by a vertical clearance 128. After ink has been applied on the screen mask 124, an edge of the squeegee contacts the screen mask 124 and the squeegee is moved across the mask with enough pressure to deform the mask and depress the mask through the clearance 128 to contact the substrate 126. In other words, the squeegee squeezes the ink 122 through meshes of the screen mask 124 in the desired pattern area and ink from the desired pattern is printed on a substrate 126. The printed layer is cured in an oven between 100-180° C., for example, between 130-150° C., or at 140° C.

The screen mask 124 can be made from stainless steel wires. The diameter of the wire can be 25-45 μm, with a mesh thickness of 55-70 μm, and the mesh can have openings of 40-80 μm in width. The open area on the mask can be between 40-45% of its total area. Patterned areas on the mask are defined by open areas. Regions where ink should not be deposited onto the substrate are covered by an emulsion layer that blocks ink from the underlying substrate layer. When the mask is too deformable, the printed pattern can become less sharp. However, when the mask is too rigid, it becomes more difficult to deform the mask to allow it to contact the substrate for the ink to be transferred thereon. Similarly, when the clearance 128 is too small, the printed pattern can become less sharp as surface tension of the ink can cause smudging in adjacent areas on the substrate when the mask retracts from the deformed state. The clearance 128 can be about 1.25 mm for printing of the silver electrode, and can be about 1.50 mm for the printing of the dielectric layer. The average particle size of the barium titanate dielectric material is about 1 μm in diameter and the average particle size of the silver particles is about 200 nm. When the clearance 128 is too large, the mask would have to be deformed to a larger extent to contact the substrate. Ink properties, such as its viscosity and the particle size of the material can also influence the quality of the printed layer. Inks having a smaller particle size allow a thinner screen-printed layer to be deposited. The electrical performance of the TFT can improve when a thinner dielectric layer is used. A squeegee angle 125, printing speed and pressure are also factors that can influence the quality of the printed layers.

In addition, X-Y-θ adjustment micrometers on the printer 123, in the form of a translation stage 130 used to support the substrate can be used to obtain better alignment between different layers (e.g., between the source electrode layer and the dielectric layer). The mask 124 is held in a fixed position and the substrate can be translated or rotated relative to the fixed mask.

FIG. 1D shows an optical image of printed 12×10 TFT arrays 160 on a Si/SiO₂ substrate. FIG. 1E shows an optical image of printed TFT array 162 on a PET substrate. The SWCNT network 164 is inspected by field-emission scanning electron microscopy (FE-SEM) as shown in FIG. 1F.

BTO ink and Ag inks can be obtained from commercial sources and then diluted using diethylene glycol ethyl ether acetate as the solvent to form diluted inks of different volume ratio (Vₛₒₗ/Vₘₖ). Different concentrations of BTO ink and Ag ink can be used to optimize performance of the printed TFT.

For example, silver ink such as AG-959, from Conductive Compounds Inc., of Hudson, N.H., and BTO ink such as BT-101, from the same company can be diluted by diethylene glycol ethyl ether acetate (e.g., Solvent 20, from the same company). Thicknesses of printed layers can be measured by a profilometer (Dectak II, Veeco of Fremont, Calif.). During printing, the screen printer (ZT-320, TOPRO Ltd.) was manually operated with the squeegee angle 125 of 80 degree and clearance of 1.25 mm for silver ink and 1.5 mm for BTO ink, at a printing speed 30 cm/s. After printing, samples were baked in an oven (Blue M 0V-8A) at 140° C. for 2 minutes (for silver electrode) or 8 minutes (for BTO dielectric). Electrical measurements were carried out using an Agilent Semiconductor Parameter Analyzers 4156B under ambient conditions.

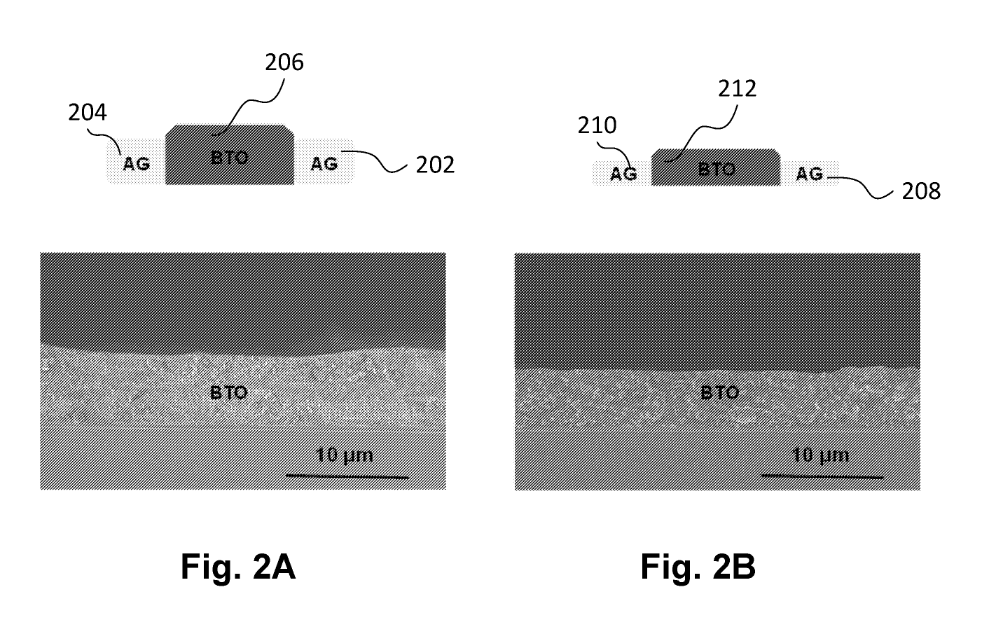

FIGS. 2A and 2B illustrate the influence capillary effect has on thicknesses of printed BTO layers, particularly for BTO layers printed with different dilution conditions. The figures show a printed source electrode 202 made of Ag, and a printed drain electrode 204 made of Ag. These electrodes are printed with diluted silver ink (Vₛₒₗ/Vₘₖ=1:4). Diluted BTO ink (Vₛₒₗ/Vₘₖ=1:4) is then used to print a gate dielectric 206. Interestingly, dilution of Ag ink for source electrode and drain electrodes can influence the thickness of the subsequent printed BTO dielectric, which can have a direct impact on the device performance. Capillary effect may play a role in the solution-based printing process. After the printing of the source electrode and the drain electrode, a “trench” with width=105 μm in the channel region is formed between the rather high source and drain electrodes depicted in FIG. 2A. A deeper trench formed by less-diluted Ag source and drain would have stronger capillary effect and thus more BTO material would be trapped in the trench when BTO was printed. Hence, the resulted printed BTO is thicker than the BTO layer when the source and drain electrodes are printed with more-diluted ink. For the same BTO ink having a volume ratio Vₛₒₗ=1:4, the BTO dielectric layer that results when 1:3 diluted Ag ink was used for source and drain is 5 μm in thickness and thinner than the 6.5 μm BTO layer when 1:4 diluted Ag ink was used for source and drain patterning.

In FIG. 2B, a source electrode 208 and a drain electrode 210 are printed with diluted silver ink (Vₛₒₗ=1:3) and a gate dielectric 212 is printed with diluted BTO ink (Vₛₒₗ=1:4). The result shows a thinner BTO layer (−5 μm) in FIG. 2B compared with the BTO layer (6.5 μm) in FIG. 2A.

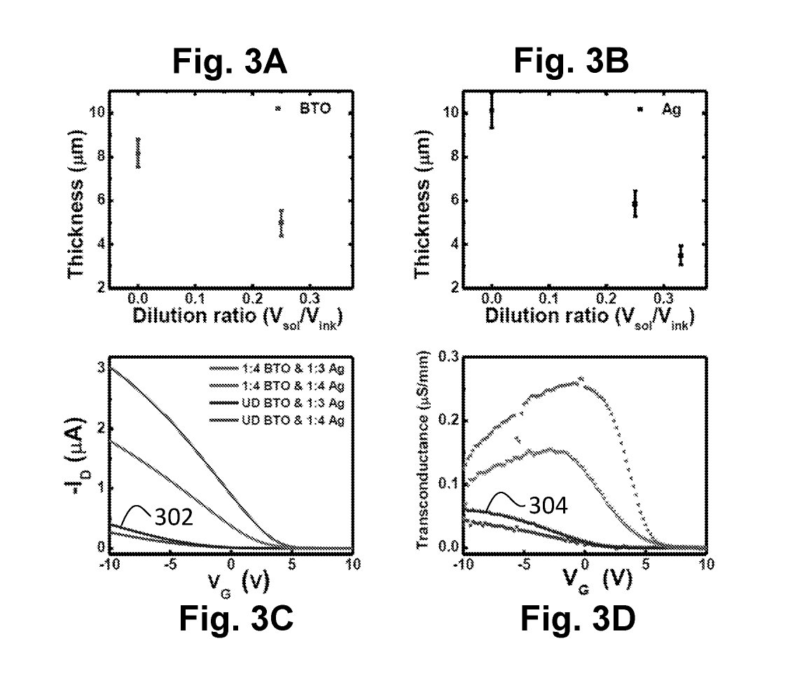

Due to the nature of screen printing, ink used for this technique are generally of high viscosity, which results in relatively thick printed layers. High viscosity can refer to ink having a viscosity of greater than 2000 cP. Relatively thick printed layers can refer to thickness greater than 1 μm. The characteristics of TFTs printed with different ink dilution ratios are shown in FIG. 3A-3D. These data are derived from exemplary TFTs fabricated with a channel length (L) of appropriately 105 μm and a channel width (W) of about 1000 FIG. 3A shows the thickness variation of printed BTO layer as a function of Vₛₒₗ/Vₘₖ. FIG. 3B shows the thickness variation of the Ag layers as a function of Vₛₒₗ/Vᵢₙₖ. In FIGS. 3A and 3B, the thicknesses of undiluted (UD) BTO and Ag layers after printing are 8.1 μm and 10 μm, respectively, measured using a profilometer. The thickness variation from sample to sample was observed to be around ±0.5 μm. The thicknesses of the printed layers can be reduced by diluting the inks. For example, diluted BTO ink with Vₛₒₗ/Vᵢₙₖ=1:4 led to a printed BTO layer of 5 μm in thickness, while diluted Ag ink with Vₛₒₗ/Vᵢₙₖ=1:4 and Vₛₒₗ/Vᵢₙₖ=1:3 led to a Ag electrode of ˜6 μm and ˜3.5 μm, respectively. To facilitate printing of multiple layers for the SWCNT TFTs, Ag source and drain electrodes can have heights that do not negatively affect the printing of a subsequent BTO layer. In view of this, Ag inks diluted with volume ratios of 1:4 and 1:3 were selected for further studies.

The transfer characteristics of SWCNT TFTs printed using inks of different dilution ratios are shown in FIGS. 3C and 3D. When undiluted BTO ink was used, the printed SWCNT TFTs show low on-current (˜0.4 μA) 302 and a low transconductance (˜0.059 μS/mm) 304 at V_{G}=−10 V and V_{DS}=−1 V. Remarkably, on-current and the peak of transconductance (FIG. 3D) increased up to ˜3 μA and ˜0.27 μS/mm when the 1:4 diluted BTO ink was used for the dielectric layer. The improved on-current may be attributed to both improvement in gate capacitance and mobility when thinned dielectric was used. First of all, at a given gate voltage (V_{G}), thinner gate dielectric can lead to higher gate capacitance and stronger gate-channel coupling, and thus the number of carriers in the channel increases. Moreover, based on the multiple trap and release (MTR) model, the increased charge in the channel can lead to greater filling of interface traps, causing the ratio of free to trapped carriers to increase. As a result, devices with thinner dielectric layer can show higher field-effect mobility. Both the enhanced mobility and increased number of carriers contributed to larger drain current (I_{D}) and transconductance when diluted BTO was used.

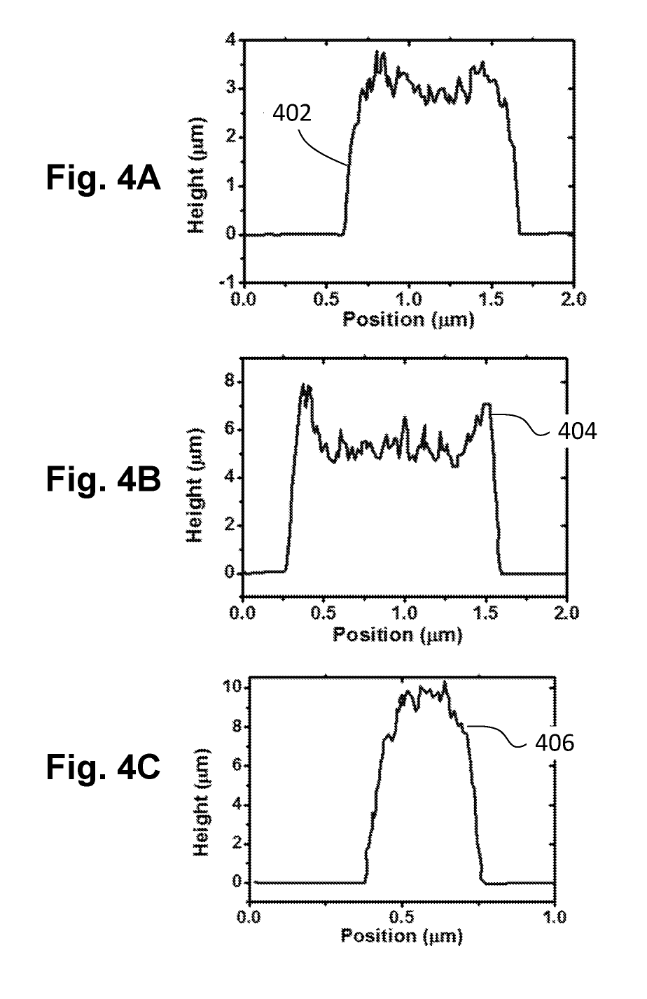

FIG. 4A shows a profile 402 of a printed electrode using 1:3 silver ink. FIG. 4B shows a profile 404 of a printed dielectric layer using 1:4 BTO ink. FIG. 4C shows a profile 406 of a printed gate electrode using undiluted silver ink. The thicknesses are approximate thickness 3.3 μm, 5.1 μm, and 9.8 μm, respectively across FIGS. 4A-4C.

In addition, Ag inks of different dilution ratios can influence the performance of printed devices even when the same kind of BTO was used for gate dielectric printing. As shown in FIGS. 3C and 3D, with the same dilution ratio of BTO, more diluted Ag ink for source and drain improved the on-current and peak transconductance. Nonetheless, over-diluted BTO (Vₛₒₗ/Vᵢₙₖ>1:4) caused gate leakage through pinholes in the gate dielectric. The ink dilution is optimized as Vₛₒₗ/Vᵢₙₖ=1:3 for Ag source and drain, and Vₛₒₗ/Vᵢₙₖ=1:4 for the BTO gate dielectric, and undiluted Ag ink for the gate electrode.

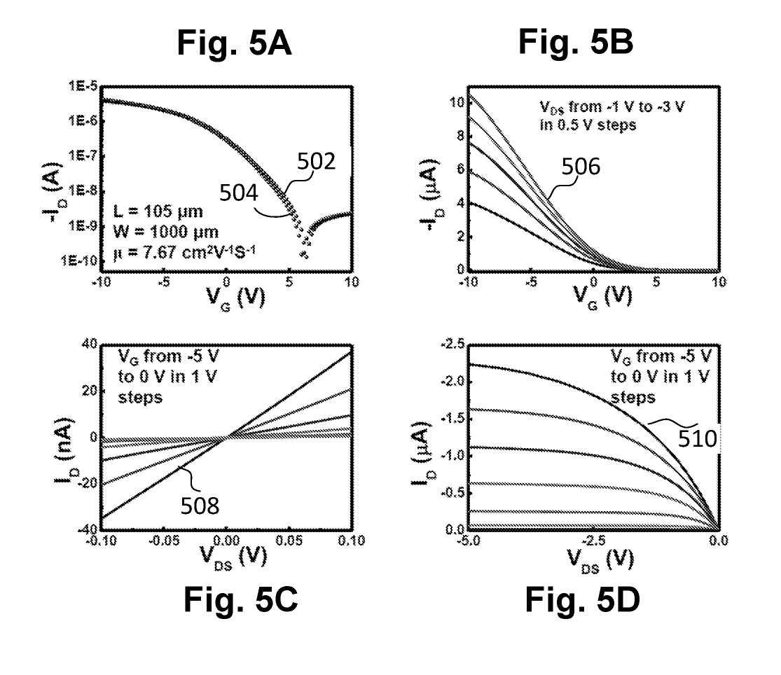

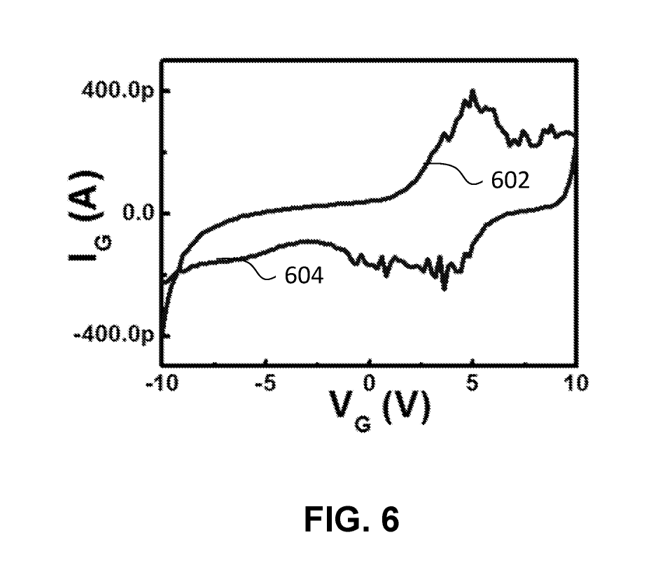

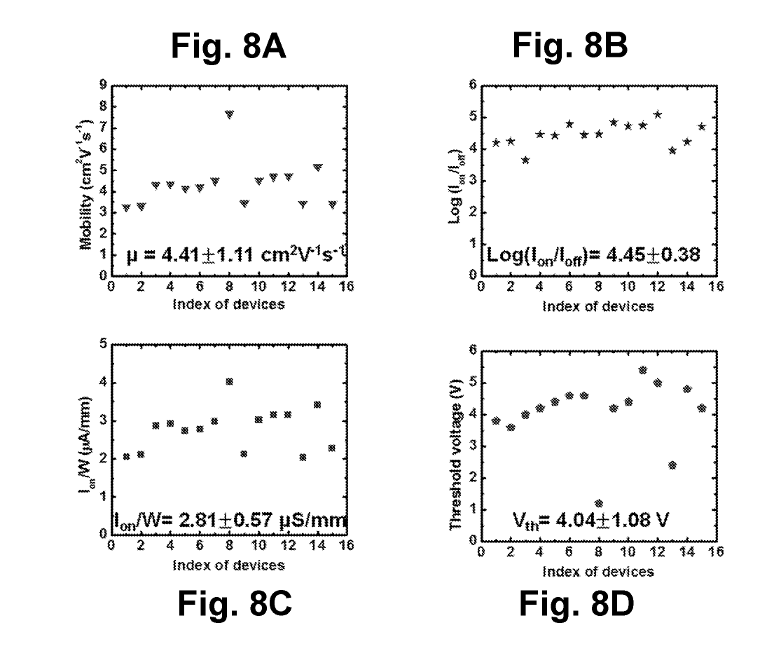

Based on the optimized dilution conditions, the electrical performance of fully printed SWCNT TFTs on rigid Si/SiO₂ substrate was further studied, as shown in FIG. 5A-5D. Transfer characteristics of a representative TFT with L=105 μm and W=1000 μm are shown in FIG. 5A. The device exhibits current on/off ratio of ˜3×10⁴, extremely small hysteresis and normalized peak transconductance of ˜0.43 μS/mm at V_{DS}=−1 V. The hysteresis can be observed by the “double-sweep” method, where the voltage is stepped from −10 V to 10V, and then down from 10 V to −10 V. The deviation between curve 502 (measured with increasing voltage) and curve 504 (measured with decreasing voltage) indicates the hysteresis of the system. The mobility can be calculated as:

$$μ = \frac{L}{W} \frac{1}{{C}_{ox} {V}_{SD}} \frac{{dI}_{SD}}{{dV}_{G}}$$

where L and W are the channel length and width of the device. V_{SD} is the source and drain voltage and is 1 V. I_{SD} is the current flowing from source to drain and V_{G} is the gate voltage. Cₒₓ is the gate capacitance per unit area and can be calculate using the following equation when the SWCNT network is likened to a uniform thin-film:

$${C}_{ox} = \frac{{ɛ}_{0} {ɛ}_{r}}{{t}_{ox}} = 6.195 \times {10}^{- 9} F \text{/} {cm}^{2}$$

where εᵣ is the relative dielectric constant of the BTO (˜35 for the BTO ink we used), co is the vacuum dielectric constant, and tₒₓ is the thickness of the BTO layer (˜5 μm). Then the calculated field effect mobility is 7.67 cm²V⁻¹S⁻¹. The gate leakage current as a function of gate voltage at V_{DS}=−1 V is shown in FIG. 6, and the small leakage current (<0.5 nA) indicates excellent insulating property of the printed BTO dielectric layer. Curve 602 shows the gate leakage current as the gate voltage is increased from −10V to 10V, while curve 604 shows the gate leakage current as the gate voltage is decreased form 10V to −10V. FIG. 6 shows the gate leakage current of a printed SWCNT TFT as a function of gate voltage at V_{DS}=−1 V. The transfer curves, including curve 506, with V_{DS} ranging from −0.1 V to 0.1 V are shown in FIG. 5B. The output curves in FIG. 5C, including line 508, exhibits a clear linear regime, illustrating good ohmic contacts between the printed Ag electrode and the SWCNT network. Additionally, current saturation due to pinch-off effect was clearly observed in curve 510 as shown in FIG. 5D. Statistical study of 15 fully screen printed SWCNT TFTs with L˜105 μm and W˜1000 μm is shown in FIG. 8A-8D, exhibiting good uniformity in terms of mobility, current on/off ratio, on-current density, and threshold voltage. The calculated average values and standard deviations are included in each figure.

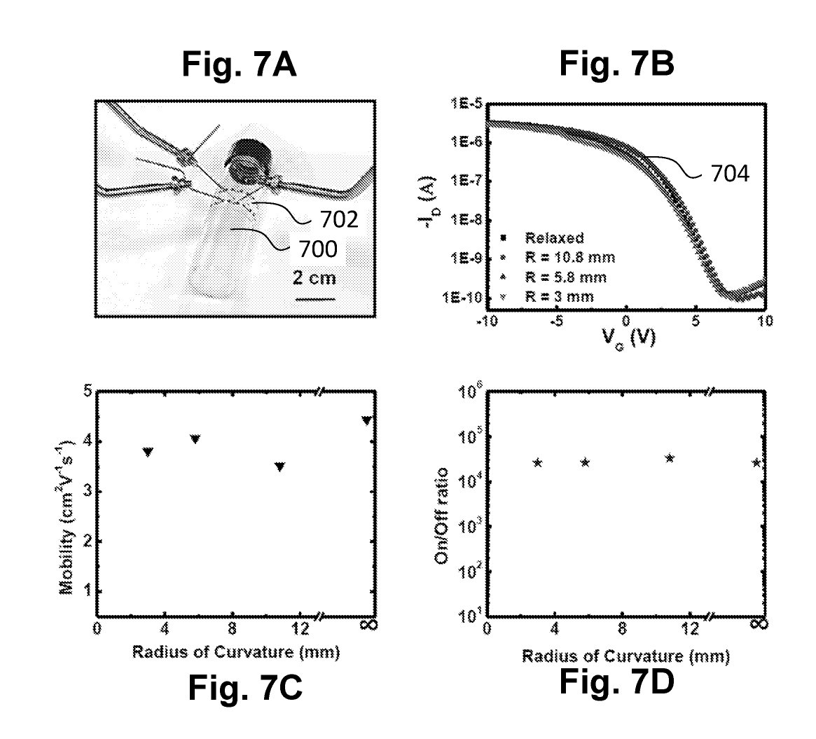

After the demonstration of fully printed high-performance SWCNT TFTs on rigid substrate, screen printing was also used in fabricating SWCNT TFTs on flexible substrate. FIGS. 7A-7D show the mechanical flexibility of fully screen-printed TFTs on PET substrate. Flexible TFTs were wrapped onto glass vials of different radii (R) during the measurement. In the measurement setup shown in FIG. 7A, the flexible TFT 702 is wrapped around a glass vial 700. The transfer characteristics 704 of different bending conditions are shown in FIG. 7B. The extracted mobility and on/off ratio as a function of bending radius in FIGS. 7C and 7D indicate that there is little measurable degradation of the flexible SWCNT TFT while bent with radius of curvature, R, down to 3 mm. R of relaxed state (i.e., unbent, flat substrate) is infinite. The results indicate good mechanical stability and flexibility of the SWCNT network and the TFT structure.

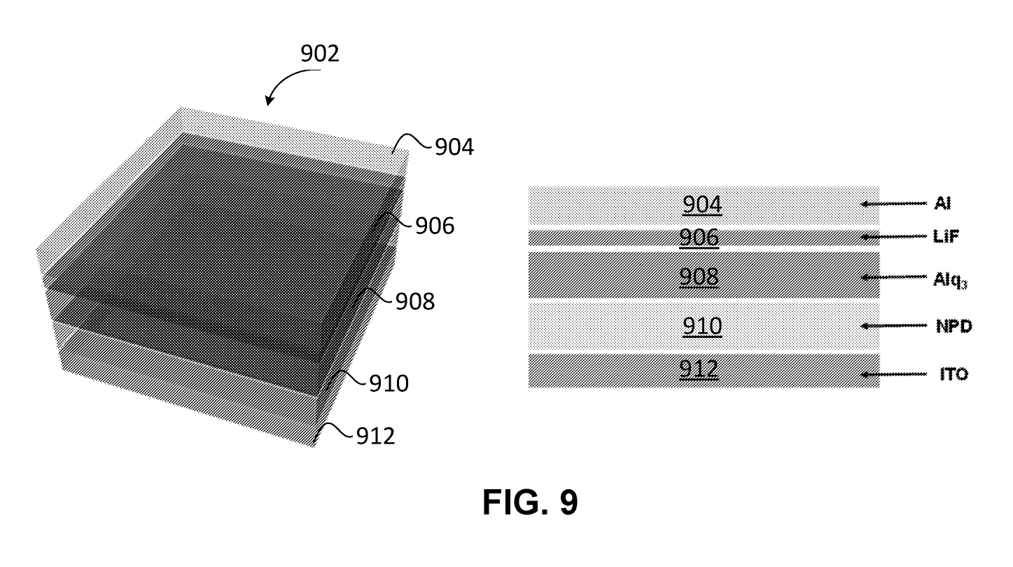

Based on the measured high on/off ratio, high mobility, small hysteresis, and low operation voltage, these fully printed low-cost SWCNT TFTs are incorporated in display electronics. For proof of concept, a typical printed top-gated TFT was connected to an external OLED 902, whose structure is shown in FIG. 9. The OLED structure 902 has an aluminum (Al) layer 904 of about 100 nm, a LiF layer 906 of 1 nm, a tris (8-hydroxyquinoline) aluminum (Alq3) layer 908 of about 40 nm, a 4,4′-bis[N-(1-naphthyl)-N-phenylamino]biphenyl (NPD) layer 910 of 40 nm and an ITO layer 912.

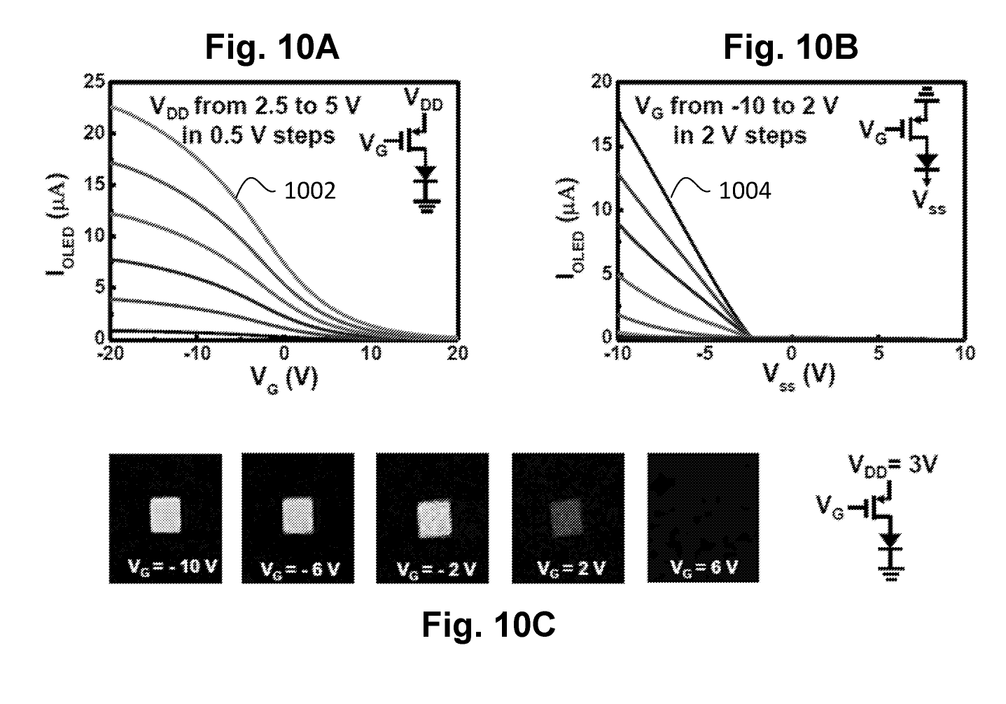

The schematic diagrams of the measured circuits are in the insets of FIGS. 10A, 10B and 10C. The current which flows through the OLED (I_{OLED}) is plotted as a function of gate voltage at different V_{DD} in FIG. 10A as shown in curve 1002. A driving current of 22.5 μA was measured at V_{G}=−20 V and V_{DD}=5 V, which is more than sufficient for driving the OLED that requires 1 μA to have observable light emission. The family curves of I_{OLED}-V_{SS} measured at different gate voltages are shown in FIG. 10B, as shown in curve 1004, and FIG. 10C indicates that the intensity of light emission changed with increasing V_{G}. The OLED was very bright at V_{G}=−10 V, V_{DD}=3 V and then the light intensity was reduced by increasing V_{G}. Eventually, the OLED was turned off at V_{G}=6 V. Based on the data above, the fully screen-printed SWCNT TFTs exhibited good OLED control capability and show potential for large-area, flexible and low-cost display electronics applications.

In summary, fully screen-printed top-gated SWCNT TFTs can be fabricated on both rigid and flexible substrates. This disclosure describes the use of semiconductor-enriched SWCNT as channel materials, together with a printed high-k gate dielectric layer. In addition, ink dilution was optimized and the printed devices exhibited a mobility up to 7.67 cm²V⁻¹s⁻¹, an on/off ratio of 10⁴˜10⁵, minimal hysteresis, a low operation voltage, and outstanding mechanical flexibility. Based on the good performance, the OLED driving capability of fully printed TFTs was demonstrated. Screen printing has great potential for mass production of large-area, cost-effective and high-performance CNT TFTs for applications in macroelectronic applications.

The printing resolution of screen printing is related to, for example, specifications of the screen mask, such as the mechanical strength of the metal mesh, the wire diameter of the mesh, and the opening ratio of the mesh. The emulsion thickness can also influence the printing resolution. When the emulsion layer covering the mesh has a smaller thickness, less ink is accumulated on the mesh, allowing a thinner layer to be printed. The quality of screen mask can be improved by the use of improved alloys that have better flexibility and strength, and which have wires of smaller diameter. Such improvements can allow screen printing to have a resolution of 6 When a line having an ideal linewidth of 100 micron is printed with a linewidth of 150 microns (i.e., 25 microns larger on each side of the line), the resolution of that system is considered to be 25 microns. Ink and substrate can also affect the printing resolution. Most of the inks used for screen printing are composed of nanoparticles, binders, and solvents. The diameter of the nanoparticles and affinity of the ink to the substrate play significant roles influencing the printing resolution. Overall, screen printing holds great promise for high-resolution printing in the future. The good electrical characteristics, low-temperature and cost-effective fabrication process, and outstanding mechanical flexibility of fully printed SWCNT TFTs suggest screen printing is very promising to become a practical technique for device and display applications.

1. A method of fabricating a thin film transistor, the method comprising:
applying a first ink containing metallic particles to a first screen mask;
using the first screen mask to deposit the first ink to form a source electrode and a drain electrode on a substrate bearing a layer of carbon nanotubes (CNT);
applying a second ink containing a dielectric material to a second screen mask;
using the second screen mask to deposit the second ink to form a layer of the dielectric material on the layer of CNT between the source electrode and the drain electrode; and
applying a third ink containing metallic particles to a third screen mask;
using the third screen mask to deposit the first ink to form a metallic gate electrode on the layer of the dielectric material to form the thin film transistor.

2. The method of claim 1, further comprising etching away CNT from regions of the substrate not covered by the source electrode, the drain electrode and the dielectric material.

3. The method of claim 1, further comprising depositing the CNT on the substrate by immersing the substrate in a solution of CNT.

4. The method of claim 3, wherein the substrate is functionalized with poly-L-lysine and the carbon nanotubes comprise semiconductor-enriched single-wall carbon nanotubes (SWCNT).

5. The method of claim 4, wherein the dielectric material comprises barium titanate.

6. The method of claim 1, further comprising aligning the second screen mask and the substrate before depositing the dielectric material, and both the second screen mask and the substrate are planar, and wherein the second screen mask is semi-transparent.

7. The method of claim 1, wherein the substrate comprises a flexible substrate.

8. The method of claim 7, wherein the flexible substrate comprises polyethylene terephthalate (PET) and a mobility of the thin film transistor is reduced by less than 20% when the thin film transistor is bent to a radius of curvature of less than 3 mm.

9. The method of claim 1, further comprising controlling a thickness of the source electrode and the drain electrode by selecting a first dilution ratio for the first ink to be deposited as the source electrode and the drain electrode on the substrate.

10. The method of claim 9, further comprising controlling a thickness of the layer of the dielectric material by selecting a second dilution ratio for the second ink.

11. The method of claim 10, wherein the second dilution ratio determines a viscosity of the second ink.

12. The method of claim 1, wherein the thin film transistor has an on-current of at least 3 μA and a peak transconductance of at least 0.27 μS/mm.

13. The method of claim 1, wherein the thin film transistor has a mobility between 7-7.7 cm²V⁻¹s⁻¹ and an on/off ratio of between 10⁴ and 10⁵.

14. The method of claim 1, wherein applying the first ink on the first screen mask comprises using a device to spread the first ink across the screen mask at a first pressure, and forming the source electrode and the drain electrode comprises squeezing the first ink through a mesh of the screen mask onto the substrate.

15. The method of claim 14, wherein the device comprises a squeegee and an edge of the squeegee contacts the first screen mask, and wherein the squeegee is configured to make an angle of between 50 to 80 degree with the substrate.

16. The method of claim 1, wherein a printing speed of the deposition of the source electrode and the drain electrode, the dielectric material, and the gate electrode depends on a rate at which the first ink, the second ink, and the third ink are squeezed through the first, second, and third masks, respectively.

17. The method of claim 1, further comprising providing a clearance of between 1 mm and 1.5 mm between the first screen mask and the substrate prior to depositing the source electrode and drain electrode on the substrate.

18. The method of claim 1, further comprising providing a clearance of between 1.25 mm and 1.75 mm between the second screen mask and the substrate prior to depositing the layer of the dielectric material between the source electrode and the drain electrode.

19. The method of claim 1, further comprising providing a clearance of between 1 mm and 1.5 mm between the third screen mask and the substrate prior to depositing the gate electrode on the dielectric material.

20. The method of claim 1, further comprising heating the source electrode and the drain electrode at a temperature between 120 to 160° C. after they have been deposited.

21. The method of claim 1, wherein the first screen mask comprises a metal mesh, the metal mesh comprises a network of wires having a wire diameter of between 28-40 microns and an opening ratio of at least 40%.

22. The method of claim 1, wherein the thin film transistor is printed on the substrate with a resolution of 25 μm.

23. A single-wall carbon nanotubes (SWCNT) thin film transistor fabricated using the method of claim 1, wherein the thin film transistor is formed on a rigid Si/SiO₂ substrate and exhibits current on/off ratio of ˜3×10⁴, and a normalized peak transconductance of ˜0.43 μS/mm at V_{DS}=−1 V, where V_{DS} is the voltage between the source electrode and the drain electrode.

24. The SWCNT of claim 23, wherein a channel length of the thin film transistor is between 90 to 120 μm and a width of the thin film transistor is between 900 μm and 1100 μm.

25. An electronic display, the display comprising:
a top-gated thin film transistor comprising a gate electrode, a source electrode and a drain electrode fabricated using the method of claim 1, and
an external organic light emitting diode (OLED) connected to the top-gated thin film transistor, wherein a driving current of between 10-25 μA flows through the OLED when a gate voltage of 5V is applied to the gate electrode and a drain voltage of 5V is applied to the drain electrode.
